(19) United States
(12) Patent Application Publication
(10) Pub. No.: US 2018/0167088 A1
(43) Pub. Date: Jun. 14, 2018

(54) Error-Correcting Code Method and System with Hybrid Block Product Codes

(71) Applicant: Futurewei Technologies, Inc., Plano, TX (US)

(72) Inventors: Kasra Vakilinia, Santa Clara, CA (US); Yunxiang Wu, Cupertino, CA (US)

(21) Appl. No.: 15/374,812

(22) Filed: Dec. 9, 2016

(51) Int. Cl. H03M 13/29; G06F 11/10; G11C 29/52; G06F 3/06

(52) U.S. Cl. CPC H03M 13/2909; G06F 11/1068; G06F 3/0679; G06F 3/0619; G06F 3/064; G11C 29/52

(57) ABSTRACT

A method including mapping an address space of the buffer configured to store a plurality of data values into a first two-dimensional array of values. For each row in the first two-dimensional array, calculating, by a processor comprising an encoder, a row parity value. For each row, a plurality of data values in the row and the row parity value form a row codeword. For each column in the first two-dimensional array, a column parity value is calculated by the processor comprising an encoder, wherein for each column, a plurality of data values in the column and the column parity value form a column codeword. The exclusive-OR (XOR) of the plurality of data values is calculated. A parity value based on the XOR of the plurality of data values is calculated by the processor comprising an encoder.

### CROSS-REFERENCE TO RELATED APPLICATIONS

None.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Data stored in non-volatile memory devices, such as flash memory, or communicated across a communication link is subject to corruption by noise. To mitigate against such data corruption, error correcting codes (ECC) may be generated and stored in the memory or transmitted with the data across the communication link. However, in related art error correcting codes, certain error patterns cannot be corrected. These lead to performance degradation of the system in which they are employed, and, in the case of flash memory for example, may lead to error floors that exceed acceptable levels for such systems.

### SUMMARY

In related art, error correction code (ECC) schemes which may be used in non-volatile memory devices such as flash memory, or in any communication system, certain error patterns may be uncorrectable. Consequently, such systems may have residual uncorrected errors that exceed the levels desired in the particular system. For example, a flash memory device may have an uncorrected bit error rate (UBER) specification of not more than 10⁻¹⁵, which may be difficult to achieve using typical related art ECC techniques, referred to as block product codes (BPC). To resolve this, and as will be more fully described below, a hybrid block product code may be used to reduce the error floor. A hybrid block product code includes an encoding of a set of data into row and column codewords based on a mapping of the data into an array. Further, the data is exclusive-OR'ed, cell-by-cell, and the result encoded to form an additional codeword, which may be referred to as an exclusive OR (XOR) codeword. After decoding the row and column codewords, the XOR codeword may be used to correct remaining errors. Such hybrid block product codes may be particularly suited to reducing the error floor in the presence of error patterns that are not corrected by BPC schemes alone.

In an embodiment, the disclosure includes mapping an address space of a buffer configured to store a plurality of data values into a first two-dimensional array of values. For each row in the first two-dimensional array, a row parity value is calculated, wherein for each row, a plurality of data values in the row and the row parity value form a row codeword. For each column in the first two-dimensional array, a column parity value is calculated, wherein for each column, a plurality of data values in the column and the column parity value form a column codeword. The XOR of the plurality of data values is calculated. A parity value based on the XOR of the plurality of data values is calculated. The XOR of the plurality of data values and the parity value based on the XOR of the plurality of data values form an XOR codeword. The row codewords and the column codewords are configured to correct, when decoded, a first preselected number of errors in each row and column codeword (four in the example above) resulting during storage of the codewords in a memory device or in transmission of the codewords across a communication link, and the XOR codeword is configured to correct, when decoded, a second preselected number of errors in the XOR codeword (twelve in the example above) resulting during storage of the XOR codeword in a memory device or in transmission of the XOR codeword across a communication link. a XOR data value based on the XOR codeword when decoded is configured to correct a data value in a cell of the two-dimensional array having a number of errors greater than the first preselected number of errors. The decoded row and column codewords and the corrected data value in the cell of the two dimensional array comprise error free data values corresponding to the plurality of data values stored in the memory device or transmitted across a communication link

In an embodiment, the disclosure includes an apparatus having a buffer controller configured to map an address space of a buffer to a two-dimensional array. An encoder is coupled to the buffer controller and configured to receive a plurality of data values mapped from the buffer address space to the two-dimensional array, calculate a row parity value for the data values in each row of the two-dimensional array, and calculate a column parity value for the data values in each row of the two-dimensional array. An XOR logic coupled to the encoder and configured to calculate the XOR of the data values, wherein the encoder is further configured to calculate an XOR parity value based on the XOR of the data values, and the buffer controller is further configured to store each row parity value, each column parity value and XOR parity value in the buffer.

In an embodiment, the disclosure includes a communication system including a transmitter system, a receiver system, and a communications link therebetween. The transmitter system includes a first buffer controller and a first buffer coupled to the first buffer controller. The first buffer controller is configured to map an address space of the first buffer into a first two-dimensional array. The transmitter system also includes an encoder coupled to the buffer controller, the encoder configured to receive a plurality of data values mapped from the first buffer address space to the first two-dimensional array, calculate a row parity value for the data values in each row of the first two-dimensional array, and calculate a column parity value for the data values in each row of the first two-dimensional array. Also included is first exclusive-OR (XOR) logic coupled to the encoder configured to calculate the XOR of the data values, wherein the encoder is further configured to calculate an XOR parity value based on the XOR of the data values, and the buffer controller is further configured to store each row parity value, each column parity value and XOR parity value in the buffer. The row and column parity values and corresponding row and column parity values form row and column codewords, respectively, and the XOR of the data values and the XOR parity value comprise an XOR codeword. The transmitter system also includes a transmitter coupled to the buffer controller and the communications link, wherein the buffer controller is further configured to forward the row, column and XOR codewords to the transmitter. The receiver system includes a receiver coupled to the communications link, a second buffer controller coupled to the receiver, and a second buffer coupled to the second buffer controller, the second buffer configured to store row, column and XOR codewords received over the communications link. The second buffer controller is configure to map an address space of the second buffer into a second two-dimensional array corresponding to the first two dimensional array. The receiver system also includes a decoder configured to receive a plurality of codewords mapped from the second buffer address space to the second two-dimensional array, decode the row codewords and column codewords to recover the plurality of data values, and decode the XOR codeword. The receiver system further includes second XOR logic coupled to the decoder wherein, if, based on the decoded row and column codewords, one or more errors remains in a data value, the second XOR logic is configured to correct the one or more errors based on the decoded XOR codeword.

For the purpose of clarity, any one of the foregoing embodiments may be combined with any one or more of the other foregoing embodiments to create a new embodiment within the scope of the present disclosure.

These and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 shows an example two-dimensional array of data values and parity values which may be used in accordance with an embodiment of the disclosure.

FIG. 2 shows a schematic of a buffer which may be used in accordance with an embodiment of the disclosure.

FIG. 3 shows an example two-dimensional array of error values which may be used in accordance with an embodiment of the disclosure.

FIG. 4 shows an example two-dimensional array of error values which may be used in accordance with an embodiment of the disclosure.

FIG. 5 shows an example two-dimensional array of error values which may be used in accordance with an embodiment of the disclosure.

FIG. 6 shows an example two-dimensional array of data values and parity values which may be used in accordance with an embodiment of the disclosure.

FIG. 7 shows a graph of uncorrected bit error rates.

FIG. 8 is a block diagram of an apparatus in accordance with an embodiment of the disclosure.

FIG. 9 is a block diagram of a communication system in accordance with an embodiment of the disclosure.

FIG. 10 is a flowchart of a method in accordance with an embodiment of the disclosure.

### DETAILED DESCRIPTION

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the example designs and implementations illustrated and described herein, but may be modified within the scope of the appended claims along with their full scope of equivalents.

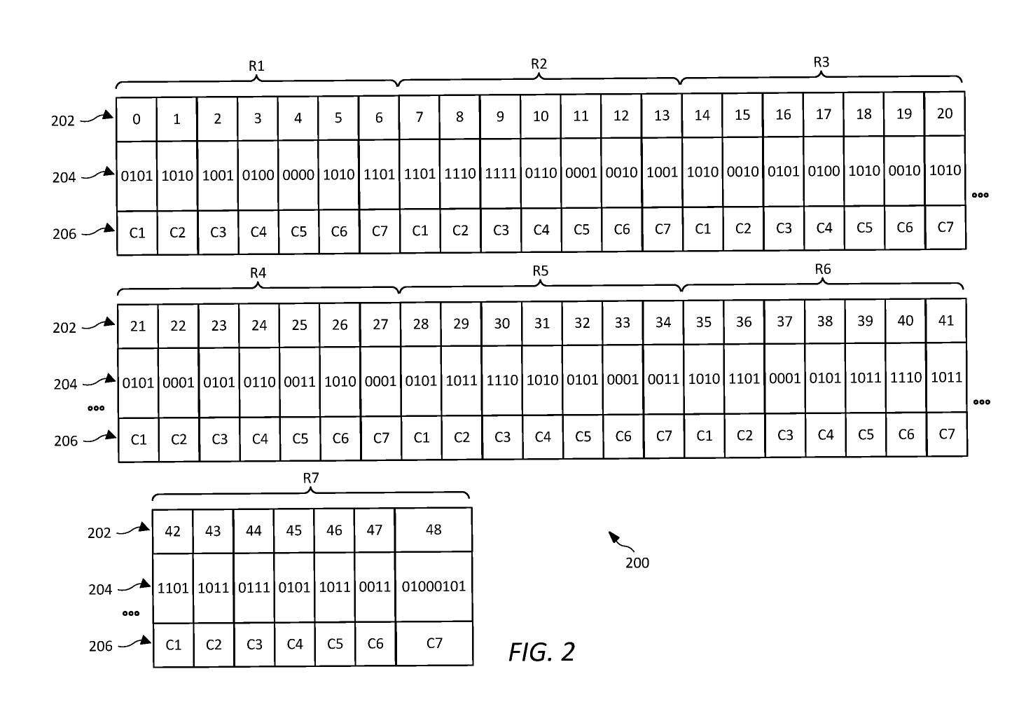

A buffer controller 804 intermediates transactions between buffer 802 and encoder/decoder 806. In at least some embodiments, a buffer controller 804 and encoder/decoder 806 may be components of a processor 805. For example, processor 805 may comprise a processor core 850 such as a microcontroller core or a microprocessor core. Buffer controller 804 and mapping module 807 are, in this example embodiment, embedded firmware associated therewith that comprises instructions that perform buffer transactions and construct the mapping between the address space of the buffer and the two-dimensional array of the data, respectively. And encoder/decoder in such an embodiment may be a hardware codec embedded within processor 805. In intermediating transaction between buffer 802 and encoder/decoder 806, buffer controller 804 maps the address space of buffer 802 into the rows and columns of a two-dimensional array representation of the data, such as that described above in conjunction with FIG. 2. Thus, for example, buffer controller 804 fetches the data from buffer 802 via I/O port 809 and a bus 811 coupled to buffer 802. I/O port 809 may, in at least some embodiments of a CPU core 850, constitute a port of a peripheral parallel port. The data is forwarded, as described further below, to encoder/decoder 806 through I/O port 813. I/O port 813 may, in at least some embodiments of a CPU core 850, constitute a port of an internal peripheral bus, such as an Advanced Peripheral Bus (APB). In other, alternative embodiments, buffer controller 804 may be an application specific integrated circuit (ASIC). In still other embodiments, as described below, buffer controller 804 may be a component of a flash memory controller.

Disclosed herein are methods and systems for error-correcting encodings of data, which may be subject to errors during storage or transmission across a communication link. The encodings are based on a mapping of the data into a two-dimensional array. Encoding the rows and columns of the array using an error-correcting code, such as Bose-Chaudhuri-Hocquenghem (BCH) encoding scheme, generates a set of parity bits that are concatenated with the data to form a plurality of row and column codewords that are stored in a memory device or transmitted across a communication link. The codewords, when decoded, are capable of correcting a preselected number of errors introduced during storage or transmission of the codewords. Further, an exclusive-OR (XOR) of the data values is calculated and encoded using a second BCH encoding capable of correcting a preselected number of errors, which may be different than the number of correctable errors in the row and column codewords, in the codeword formed by concatenating the XOR data value and the parity bits generated by the BCH scheme. This XOR codeword is also stored or transmitted across the communication link. If, after decoding the row and column codewords, residual errors clustered in a cell of the array remain, the corrected XOR data value from the decoded XOR codeword can then be used to generate the value that is otherwise uncorrectable.

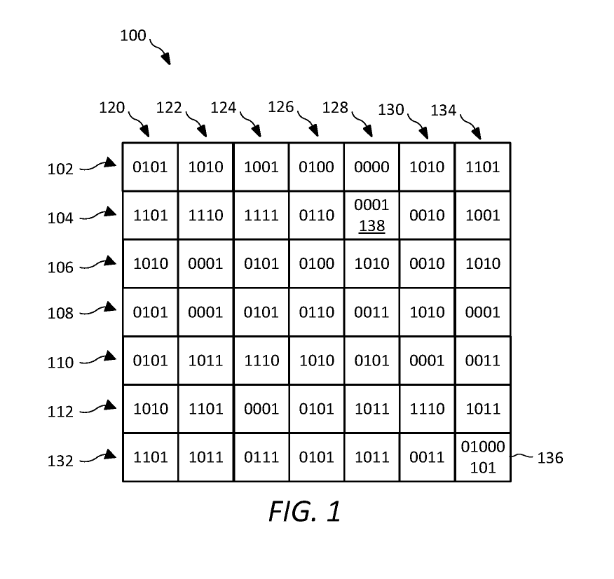

FIG. 1 shows a two-dimensional array 100 of data values and parity values, which may be found in a memory and are used in conjunction with an embodiment of the disclosure. The data values, comprising the entries in the cells of rows 102-112 and columns 120-130 of array 100, may represent data values to be stored in a flash memory device for example. The entries in row 132 and column 134 represent parity values that may be calculated as described further below. The data values in each row 102-132 and the respective parity value in column 134, may each constitute an ECC codeword which will be referred to as a row codeword. Similarly, the data values in columns 120-130 and the respective parity value in row 132 may each constitute an ECC codeword which will be referred to as a column codeword. The data values are, for ease of illustration, shown as four-bit values. However, data values of any number of bits may be used, and other examples will be described below. However, in the context of error correcting codes in flash memory applications, the available size of the flash memory may provide practical constraints on the size of the data values and parity values. By way of example, the codeword associated with row 104 is 1101111011110110000100101001. Similarly, the column codeword associated with column 122 is 101011100001001101111011011. The entry in cell 136 is a parity value that is not associated with either a row codeword or a column codeword. The calculation of the parity value in cell 136 may be based on a Bose-Chaudhuri-Hocquenghem (BCH) encoding of the exclusive-OR of the thirty-six data value entries in row 102, column 120 through row 112, column 130. The BCH encoding and representation of its associated codeword will be described below in conjunction with FIG. 6 illustrating another example of the principles of the disclosure.

The data values populating the two-dimensional array 100 (FIG. 1) may represent a mapping from an address space of a device physically storing the values, perhaps temporarily, such as a buffer. To further appreciate how such a mapping may be constructed, FIG. 2 shows a schematic of a buffer 200 storing the example data and parity values of the two-dimensional array in FIG. 1. The address space of buffer 200, represented by addresses 202. While the addresses 202 are shown, for ease of illustration as starting with address “0” and contiguous through address “48”, in general, the addresses 0-48 may be relative addresses, and further, the address space need not necessarily be contiguous, with the writing to and reading from the buffer under the control of a memory manager that may track the mapping from the array to the buffer. Further, the four bits of the example data values are taken to be addressed by a single address. In buffer 200, the mapping is, by way of example, row-wise, with the rows corresponding to rows 102-112, and 132 in FIG. 1 denoted by R1-R7, to simplify the notation and to avoid confusion with figure reference numerals used as reference numerals. The buffer entries 204 correspond to the thirty-six data values in array 100 in FIG. 1 and the parity values in column 134 in FIG. 1. The corresponding column mappings 206 are, similar to the row mapping, are denoted as C1-C7. Further, buffer 200 also stores the column parity values at addresses 42-47. The parity value in cell 136 in FIG. 1 is stored in buffer 200 at address 48.

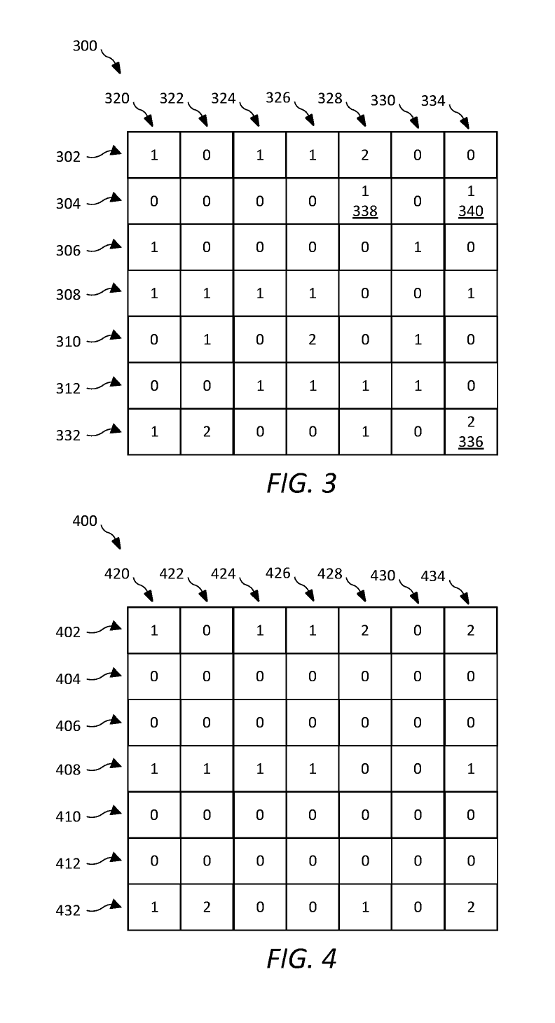

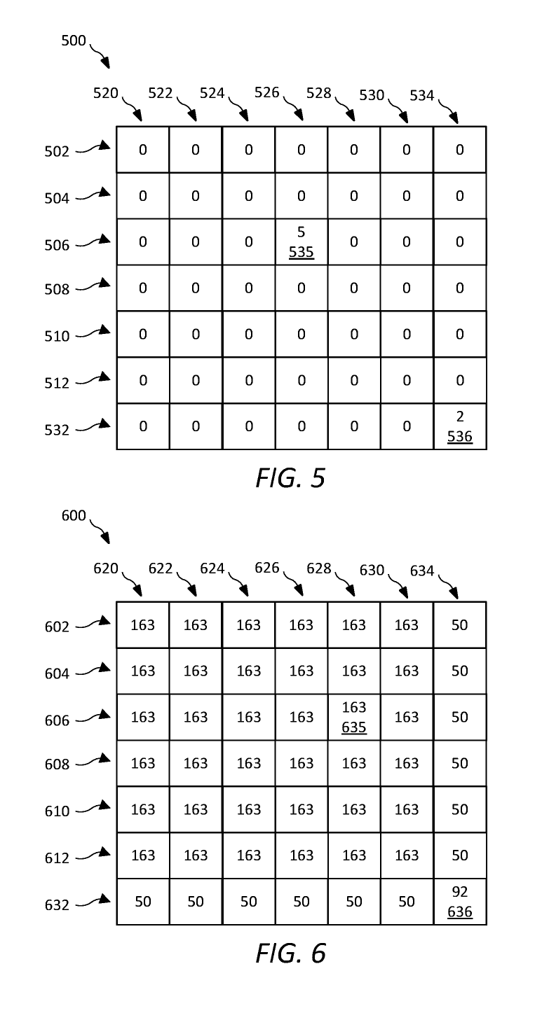

FIG. 3 shows a two-dimensional array 300 in which the entries in rows 302-312 and columns 320-330 reflect an example number of errors in the corresponding data values and parity values in two-dimensional array 100 in FIG. 1. The example number of errors is illustrative to demonstrate the principles of the disclosure. Further, an example number of errors of two bits in cell 336 represent an error of two bits in the parity value in cell 136 in FIG. 1. Again, the error of two bits represented in cell 336 is by way of example, and will be discussed further in conjunction with FIG. 5 below. Considering row 302 in the example of FIG. 3, a total of seven errors in the row codeword of FIG. 1 corresponding to row 302 are shown. If, by way of further example, the parity value in row 102 in FIG. 1 is based, for example, on a BCH encoding scheme chosen to correct up to four errors (which includes errors in the parity values) then errors in the row codeword corresponding to row 302 cannot be corrected. Conversely, represented by the two example errors in row 304 of two-dimensional array 300, the errors in the corresponding row codeword of row 104 in FIG. 1 are correctable by such a BCH encoding, and the error in the data value in cell at the intersection of row 104 and column 128 in FIG. 1, represented by the value “1” in cell 338 is corrected, along with the error in the parity value, represented by the, “1” in cell 340. Similarly, such a code can correct the errors in codewords corresponding to rows 106, 110, and 112 in FIG. 1. These are represented by the example error values in rows 306, 310 and 312, which sum to four or fewer errors. The errors in the codewords corresponding to rows 102, as described above, and 108 are not correctable by the example BCH code capable of correcting four errors. Stated otherwise, the corresponding row codewords are not valid BCH codewords, and do not represent the data values and parity values from which they were formed in the encoding process. Further, as shown in the entries in row 332, columns 320-330, the column parity values in columns 120-130 in FIG. 1, have the example number of errors of one, two, zero, zero, one and zero, respectively. Once the BCH codewords corresponding to rows 304, 306, 310, and 312 are decoded and the errors corrected thereby, the error values are reduced to zero. This reflected in the two-dimensional array 400 in FIG. 4.

Turning to FIG. 4, the entries in array 400 show the remaining errors after decoding the row codewords corresponding to the rows 304, 306, 310 and 312 in FIG. 3. As described above, these codewords were correctable by an example BCH encoding capable of correcting up to four errors. Rows, 402, 408 include seven errors and five errors, respectively. Thus, these row codewords, having more than four errors in this example, do not decode into a valid codeword. Thus, in this example, the number of errors in rows 402 and 408 correspond to the number of errors in rows 302 and 308 in FIG. 3. The column codeword corresponding to column 420 includes three one-bit errors represented by the entries at row 402, 408 and 432. Upon decoding the column codeword based on an encoding scheme that corrects four errors, the decoding will remove all remaining errors in the codeword, and the previously corrupted data values recovered. Similarly, the column codeword corresponding to column 422 has a single bit error in the portion of the codeword corresponding to the entry at row 408, and a two-bit error in the parity value portion of the codeword, as represented by the value “2” in the entry at row 432. Again, decoding the column codeword corresponding to column 422 based on the encoding scheme capable of correcting up to four errors removes the remaining errors in the codeword. Continuing with the example, in like fashion, the two errors in the column codewords corresponding to columns 424 and 426, at rows 402 and 408, can be corrected; the three errors in the column codeword corresponding to column 428, a two-bit error at row 402 and a single bit error at row 432 can be corrected. There are no errors in the column codeword corresponding to column 430. The zeros in the entries in rows 404, 406 and 410 and 412 reflect the corrections in the row codewords described above. The errors corresponding to the row parity values appearing in the entries in column 434, rows 402-412 are irrelevant as they reflect errors in the parity bits of the row codewords, and are not a column codeword. In the example of FIG. 4, all the column and row codewords have been decoded, thereby correcting all corrupted data values. Although the error patterns reflected in the example in FIG. 4 were all correctable in a so-called block product code (BPC) scheme capable of correcting four errors, other error patterns, which may have a significant probability of occurrence are problematic, and can give rise to unacceptable uncorrected bit error rates (UBER) in flash memory applications, for example. FIG. 5 shows a two-dimensional array 500 reflecting an error pattern of this kind.

Turning to the two-dimensional array 500 in FIG. 5, an example error pattern comprising a 5-bit error in a single cell, 535, in a data value corresponding to cell 535. For example, as will be described in conjunction with FIG. 6, a more realistic set of data values in the context of a flash memory ECC may correspond to data values comprising 163 bits each. In that context, the error pattern shown in array 500 may correspond to an error in five of the 163 bits in the data value corresponding to cell 635 at the intersection of row 606 and column 626 in FIG. 6. Such patterns of multiple bit errors in a single cell with few or no errors otherwise may be determined probabilistically to occur relatively frequently, and may give rise to error floors in ECC systems that are unacceptably high, as described earlier, if not otherwise corrected. Notwithstanding the freedom from errors in the corresponding codewords represented by the zeros in rows 502, 504, 508-512 and columns 520-524 and 528-530, codewords capable of correcting up to four errors cannot correct the errors in the row codeword corresponding to row 506 or the column codeword corresponding to column 526. Further, additional errors, here in the parity bits of the codeword corresponding to the XOR over the data values, as described above in conjunction with FIG. 1, and additionally in conjunction with FIG. 6 below, are represented by the value “2” in cell 536. A mechanism to correct for error patterns such as the example pattern in array 500 will be described below.

To further appreciate the principles of the disclosure, FIG. 6 shows a two-dimensional array 600 with entries that may more realistically represent a codeword size in the context of a flash memory ECC, for example. In the array 600, the entries in rows 602-612 and columns 620-630 represent a 163-bit data value. The entries in row 632, columns 620-630 represent a 50-bit parity value based on a BCH encoding that is capable of correcting up to four errors (commonly denoted as t=4). Similarly, the entries in column 634, rows 602-612 represent a 50-bit parity value. Thus, the row and column codewords comprise 1028 bits in this example (6×163 data bits+50 parity bits). These codewords would thus represent about 24 kilobytes (KB) of storage in a flash memory device, for example. The entry in cell 636 represents a 92-bit parity value that may be generated by calculating the exclusive-OR (XOR) of the thirty-six 163-bit entries in rows 602-612 and columns 620-630 and encoding the result using a BCH code. The XOR may be represented by equation (1):

⊕_{i,j=16}V(Rᵢ,Cⱼ) (1)

V(Rᵢ,Cⱼ) where represents the data value in the iₜₕ row and jₜₕ column of the array 600. Here the more conventional notation of labeling the rows (R) and columns (C) of two-dimensional array 600 by respective indices running from 1 to 6 has been used. A BCH codeword, having length of 255 bits comprising the 163 bit XOR, ⊕_{i,j=1,c}V(Rᵢ,Cⱼ), _{and} 92 parity bits may be generated by using a BCH encoding which may be capable of correcting up to twelve errors, or t=12, sufficient to correct an error pattern as exemplified in array 500 in FIG. 5. This encoding may be denoted BCH (255, 163, 12). In the following, this 255-bit BCH encoding of the XOR of the data values may be referred to as the XOR codeword, or alternatively as the short BCH codeword. By way of example, the capability of correcting 12 errors may be based on binomially distributed bit errors with a single-bit error probability of 0.001. In this example, based on a BPC error correction capability of four bits, t=4, as described above, the probability of more than four errors in a single cell greater than four is about 8×10⁻⁷. A short BCH codeword of length 255 comprising 163 data bits and 92 parity bits, as described above, with a capability of correcting at least 11 bits therein may reduce the probability to an UBER of about 10⁻¹⁵ or less.

To correct an otherwise uncorrectable error of the kind described in conjunction with FIG. 5, a determination of the corrupted data value may be based on the short BCH codeword. That is, the encoded XOR of the data values may be used to correct the otherwise corrupted data value. All other errors in the data values have been corrected, as exemplified by the “zeros” in all cells in rows 502-512 and columns 521-530 in FIG. 5, except cell 535. Further, there remains a two-bit error in the parity value associated with the codeword of the XOR encoding, as represented by the value “2” in cell 536 in FIG. 5. Upon decoding the short BCH codeword, however, this error will be corrected. Thus, the decoded short BCH codeword will include the XOR of the uncorrupted thirty-six data values. The uncorrupted data value corresponding to cell 502 may be recovered by summing, modulo 2, the thirty-five uncorrupted data values, and subtracting the result, modulo 2, from the XOR of the uncorrupted thirty-six data values in the decoded BCH codeword. Because addition and subtraction modulo 2 is equivalent to the XOR operation, the foregoing may be performed by XOR'ing the thirty-five uncorrupted data values and the decoded XOR of the uncorrupted thirty-six data values in the decoded BCH codeword. Denoting the value of the decoded XOR of the thirty-six uncorrupted data values by D, the aforesaid determination may be expressed by the following equation: ⊕_{i′},_{j′}V(R_{i′},C_{j′})⊕D where, defining the row, column indices of the corrupted data value by the row, column indices iₑ,jₑ, i′,j′ are defined, using set-theory notation, by iⁱ=[1, . . . , 6]Δi_{c}. j′=[1, . . . , 6]Δj_{c}. In other words, the indices i′, j′ range over the values from 1 to 6 with the exception of the row, column indices of the corrupted data value, or 3, 4 in the example of cell 502 in FIG. 5. Further, as would be appreciated by those skilled in the art having the benefit of the disclosure, because the XOR operation is associative, the order in which the values are XOR'ed is immaterial.

Although the example two-dimensional arrays in FIGS. 3-6 have been square arrays, the principles of the disclosure are not restricted to square arrays; rectangular arrays can also be used in alternative embodiments. While the examples have used thirty-six data values, the principles of the disclosure are not limited thereto and any number of data values may be used subject to constraints that might be imposed by memory size or similar considerations unrelated to the disclosed principles themselves. Further, while two dimensional arrays have been used in the examples, higher-dimensional arrays may be used, wherein the buffered data may be mapped to a three-dimensional array, for example, and codewords along each of the three dimensions generated as described above.

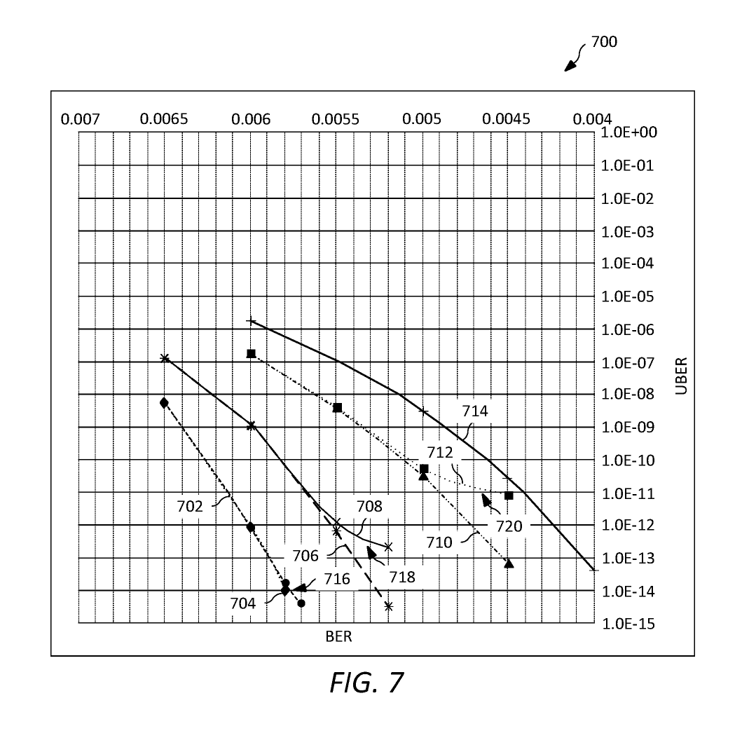

FIG. 7 shows a graph 700 in which an uncorrected bit error rate (UBER) is plotted on the vertical axis as a function of the bit error rate on the horizontal axis. The lines 702-712 plot the UBER versus bit error rate (BER) for six example encoding schemes. Note that the BER decreases from left to right in the plots. Line 702, (delimited by a line and circle data points) is based on a related-art block product code (BPC) with 16 kilobyte (KB) codewords. Generally, it is desirable to have UBER ≤10⁻¹⁴ and preferably ≤10⁻¹⁵. FIG. 7 shows that such UBER are not achievable using traditional BPC encoding schemes where the “flattening” of the UBER as the BER decreases. For example, at about a bit error rate of 0.0058, the graph begins to exhibit a noise floor at about an UBER of 1×10⁻¹⁴ as represented by the region of the graph 716 exhibiting a change in slope. This slope change may be seen more starkly in BPC schemes with shorter codewords, as in graphs 708 and 712, discussed further below. Graph 704, which includes a single point depicted with a diamond shape represents a hybrid block product coding (HBPC) scheme including the 16 KB BPC and the short BCH. The HBPC result falls below the noise-floor related region 716. The inclusion of the additional decoding of the short BCH reduces the decoding rate by about 0.11 percent relative to the 16 KB BPC alone (0.897 versus 0.898). Similarly, a HBPC comprising a BPC with 8 KB codewords and a short BCH, graph 706 (delimited by the “ [symbol] ” symbols) exhibits no noise floor as is apparent in comparison with an 8 KB BPC alone, graph 708 (delimited by the “X” symbols) which exhibits a clear change of slope region 718 beginning at a bit error rate of about 0.0055 with an UBER of about 1×10⁻¹². The HBPC exhibits a decoding rate that is about 0.2 percent slower than the BPC alone (0.896 versus 0.898). For a BPC encoding with shorter codeword, the noise floor is higher as seen in graph 712 corresponding to a 4 KB BPC encoding which exhibits a change in slope, region 720 at a bit error rate of about 0.005 with a noise floor at an UBER slightly above 1×10⁻¹⁰. The HBPC exhibits no noise floor, graph 710 (delimited by the diamond symbol). The HBPC exhibits a decoding rate that is about 0.4 percent slower than the BPC alone (0.894 versus 0.898). A 2 KB BCH encoding, graph 714 (delimited by the “+” symbols) exhibits no noise floor, it may be slower and is more complex to implement.

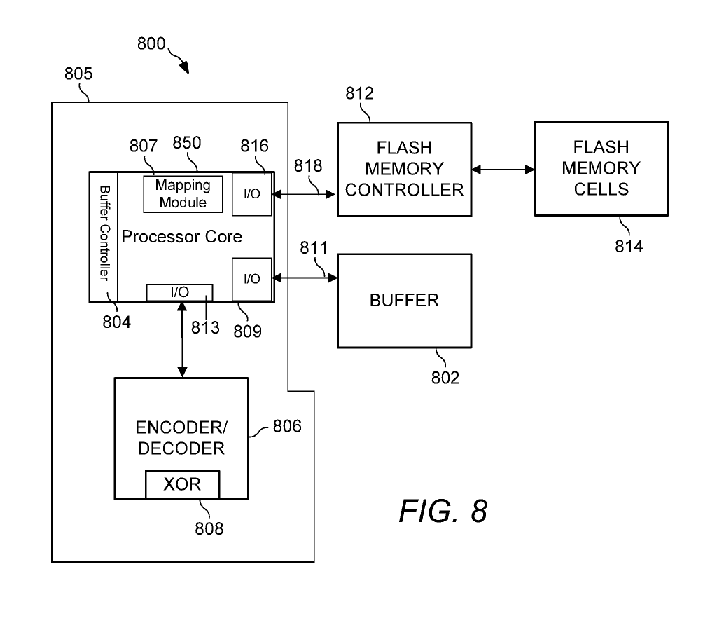

FIG. 8 shows a block diagram of an apparatus 800 for providing ECC with respect to data to be stored in a flash memory based on a HBPC embodiment. Apparatus 800 may include a buffer 802 to temporarily store the data during the encoding process. In at least some embodiments, buffer 802 comprises a plurality of hardware registers. A buffer controller 804 intermediates transactions between buffer 802 and encoder/decoder 806. In at least some embodiments, a buffer controller 804 and encoder/decoder 806 may be components of a processor 805. For example, processor 805 may comprise a processor core 850 such as a microcontroller core or a microprocessor core. Buffer controller 804 and mapping module 807 are, in this example embodiment, embedded firmware associated therewith that comprises instructions that perform buffer transactions and construct the mapping between the address space of the buffer and the two-dimensional array of the data, respectively. And encoder/decoder in such an embodiment may be a hardware codec embedded within processor 805. In intermediating transaction between buffer 802 and encoder/decoder 806, buffer controller 804 maps the address space of buffer 802 into the rows and columns of a two-dimensional array representation of the data, such as that described above in conjunction with FIG. 2. Thus, for example, buffer controller 804 fetches the data from buffer 802 via I/O port 809 and a bus 811 coupled to buffer 802. I/O port 809 may, in at least some embodiments of a CPU core 850, constitute a port of a peripheral parallel port. The data is forwarded, as described further below, to encoder/decoder 806 through input/output (I/O) port 813. I/O port 813 may, in at least some embodiments of a CPU core 850, constitute a port of an internal peripheral bus, such as an Advanced Peripheral Bus (APB). In other, alternative embodiments, buffer controller 804 may be an application specific integrated circuit (ASIC). In still other embodiments, as described below, buffer controller 804 may be a component of a flash memory controller.

Buffer controller 804 forwards the data row-by-row and column-by-column to encoder/decoder 806. In the example embodiment, encoder/decoder 806 is a hardware codec, which may, in at least some embodiments be a BCH codec. However, it would be appreciated by those skilled in the art having the benefit of the disclosure that encoder/decoder 806, may, alternatively, be implemented in software, or as an application-specific integrated circuits (ASICs). Encoder/decoder 806 is configured to generate the row and column codewords based on a BCH code having configured to generate the row and column codewords based on a BCH code having a preselected codeword length and a preselected error correction capability, for example codewords of 1028 bits and t=4 as described above in conjunction with FIG. 4 buffer controller. In at least some embodiments, encoder/decoder 806 includes XOR logic 808 to generate the exclusive-or of the data values as described above for encoding by encoder/decoder 806. Alternatively, XOR logic 806 may be provided by the general purpose arithmetic and logic unit (ALU) (not shown in FIG. 8) of the processor core 850, along with the corresponding instruction set including a machine instruction executed by the ALU to calculate the bitwise XOR of two operands, which buffer controller 804 forwards to encoded/decoder 806. It would be appreciated by those skilled in the art having the benefit of the disclosure that BCH encoder and decoders, which may be implemented in software, or as a hardware block as an application-specific integrated circuit (ASIC), for example are known in the art. Encoder/decoder 806 is configured to generate an XOR codeword based on a BCH code having a preselected number of codeword bits a preselected error correction capability, such as 255 bits and t=12 as described in conjunction with FIG. 6. Once the codewords are generated and the parity values stored in buffer 802, buffer controller 804 forwards, via flash memory controller 812, the codewords to flash memory cells 814 for storage. In at least some embodiments, a buffer controller 804 may be coupled to flash memory controller via an I/O port 816 and bus 818, which in at least some embodiments, is a serial port and bus, such as an industry standard Universal Serial Bus (USB) or a SPI bus, for example.

In alternative embodiments, buffer 802 may be a portion of random access memory (RAM) in a general purpose computer and buffer controller 804 may be implemented via application programming interface (API) calls to the operating system memory management routines. Likewise, encoder/decoder 806 and XOR logic 808 may be implemented in software routines executed in the general purpose computer. In still other embodiments, buffer controller 804, buffer 802 and encoder/decoder 806, XOR logic 808 may be an application specific integrated circuit (ASIC) or a system-on-a-chip (SOC). In still further embodiments, encoder/decoder 806 is included in flash memory controller 812. Although XOR logic 806 is shown included in encoder/decoder 806, XOR logic 808 may, alternatively be a separate logic block, Further, encoder/decoder 806 may, in alternative embodiments comprise separate devices. In yet other embodiments, combinations of the foregoing may be used in the implementation of apparatus 800. Further, the flash memory controller 812 may be included, together with the flash memory cell integrated circuit, in an integrated device, such as a Secure Digital (SD) card, for example, commonly used in conjunction with digital cameras and smartphones. In other embodiments, a flash memory controller 812 may be disposed, separately from the flash memory cells themselves, within an apparatus using the flash memory. It would be appreciated by those skilled in the art having the benefit of the disclosure that the principles disclosed herein are not limited by the architecture of the flash memory-based system in which they may be deployed.

When the data is to be retrieved from the flash memory, buffer controller 804 fetches the data from flash memory cells 814 via flash memory controller 812, and forwards the codewords to encoder/decoder 806. Upon decoding, any correctable errors that might have been introduced by the storage in the flash memory cells are corrected during the decoding operation. Further, if uncorrectable errors based on the decoding of the row and column codewords remain in a data value, XOR logic 808 is configured to correct the corrupted data value as described above in conjunction with FIG. 6. If not immediately forwarded to a consumer thereof, the corrected data values may be temporarily stored, by buffer controller 804 in buffer 802. Buffer controller 804 reads the data values and send to the consumer thereof For example, the flash memory is part of memory card used in a camera to store image data, the consumer might be image processing software in a general purpose computer coupled via a universal serial bus (USB) to the memory card via a USB-based card reader.

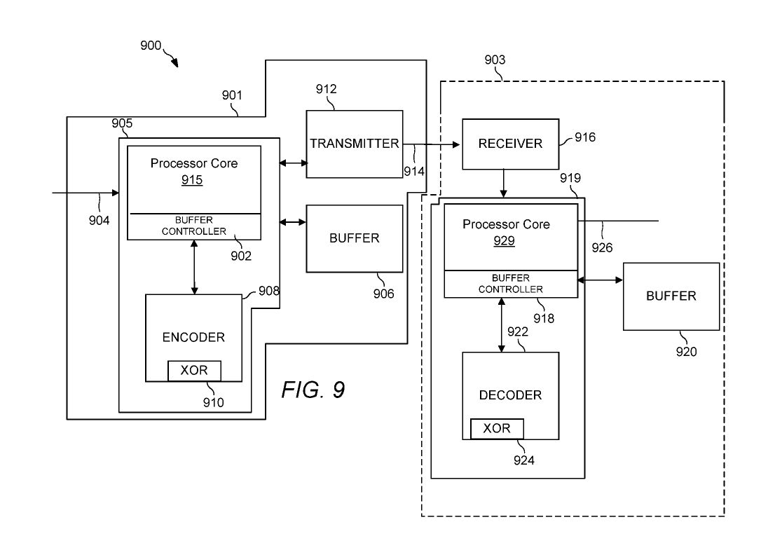

As described above, the principles of the disclosure may also be applied to communications systems, for example communication system 900 in FIG. 9 comprising a transmitter system 901 and receiver system 903. Turning to FIG. 9, a buffer controller 902 may receive data 904 to be transmitted over a communications link, such as a wireless link, optical link or electrical link. For the purpose herein, the nature of the physical link does not implicate the principles of the disclosure, although some links may be more susceptible to noise than others leading to larger bit error rates. Buffer controller 902 temporarily stores the data in a buffer 906 during the encoding process, and forward the data to an encoder while mapping the data from buffer 906 to a two-dimensional array, as previously described. Similar to buffer controller 804 and encoder/decoder 806 in FIG. 8, in at least some embodiments, a processor 905 may comprise a processor core 915, such as a microcontroller or microprocessor core, in which, in this example embodiment, buffer controller 904 is implemented in embedded firmware associated therewith. And encoder 908 may also be embedded firmware, or alternatively, a hardware codec which calculates the BCH ECC codewords. Encoder 908 then generates the parity values and buffer controller 902 may, in at least some embodiments, store the parity values in buffer 906 until all row and column codewords are generated. Encoder 908 may include XOR logic 910 to generate an XOR of the data values which may then be encoded by encoder 908, as described above. Again, XOR logic 910, although shown as included in encoder 908, may, alternatively, be implemented as a separate device, such as a plurality of XOR gates. In yet other embodiments, XOR logic 910 may comprise an ALU of processor core 915 (not shown in FIG. 9) along with a corresponding machine instruction executed by the ALU. Buffer controller 902, encoder 806 and XOR logic 910 may, in various embodiments, are implemented as described above in conjunction with FIG. 8. Buffer controller 902 then forwards the codewords to a transmitter 912 for transmission over communications link 914.

The transmitted codewords are received over link 914 at a receiver 916 and coupled to a buffer controller 918 which stores the received codewords in a buffer 920 coupled to buffer controller 910 while the codewords are decoded by decoder 922 to recover the data values, wherein all correctable errors are corrected. Similar to processor 905, in at least some embodiments, a processor 919 may, on the receiver side, comprise a processor core 929, such as a microcontroller or microprocessor core, in which, in this example embodiment, buffer controller 918 is implemented in embedded firmware associated therewith which when executed on the processor core 929 perform the buffer transactions and mappings as previously described. And decoder 922 may also be embedded firmware, or alternatively, a hardware codec for decoding the BCH codewords received at receiver system 903 over data link 914. The decoded data values may be temporarily stored in buffer 920 if not immediately transferred to a consumer thereof Further, uncorrectable errors of the type described in conjunction with FIGS. 5 and 6 are corrected via XOR'ing, in XOR logic 924, the decoded short BCH codeword with the uncorrupted data values, as described above. XOR logic 924 may be implemented in various embodiments similar to XOR logic 910. Uncorrupted data 926 is then transferred via buffer controller 918 to the consumer thereof.

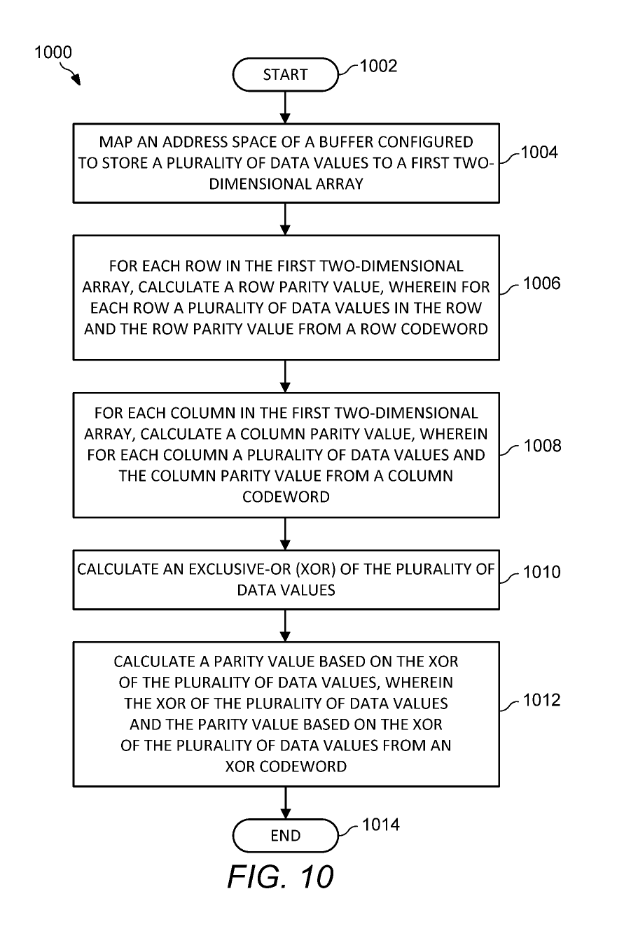

FIG. 10 shows a flowchart of a method 1000 in accordance with an embodiment. Method 1000 starts at block 1002. In block 1004, an address space of the buffer configured to store a plurality of data values into a first two-dimensional array of values is mapped. For example, the address space may be mapped by a buffer controller 804 in FIG. 8 in the context of a flash memory, of buffer controllers 902 in FIG. 9 in the context of a communication system. In block 1006, for each row in the first two-dimensional array, a row parity value is calculated, wherein for each row, a plurality of data values in the row and the row parity value form a row codeword. The row parity values may be calculated by an encoded/decoder 806 in FIG. 8 in the context of a flash memory, for example. Similarly, in the context of a communication system, the row parity values may be calculated by an encoder 908 in FIG. 9. And, in block 1008, for each column in the first two-dimensional array, calculating a column parity value is calculated, wherein for each column, a plurality of data values in the column and the column parity value form a column codeword. Similar to the row parity values, the column parity values may be calculated by an encoded/decoder 806 in FIG. 8 in the context of a flash memory. In the context of a communication system, the row parity values may be calculated by an encoder 908 in FIG. 9, for example. In block 1010, the exclusive-OR (XOR) of the plurality of data values is calculated. The XOR value may be calculated by XOR logic 808 in FIG. 8, or in the case of a communication system, by XOR logic 910 in FIG. 9. A parity value based on the XOR of the plurality of data values is calculated, block 1012. Similar to the row and column parity values, for example, in the context of a flash memory, the XOR parity value may be calculated by an encoder/decoder 806 in FIG. 8 or, an encoder 908 in FIG. 9 in the context of a communication system. The XOR of the plurality of data values and the parity value based on the XOR of the plurality of data values form an XOR codeword. Thus, the row codewords and the column codewords are configured to correct, when decoded, a first preselected number of errors in each row and column codeword (four in the example above) resulting during storage of the codewords in a memory device or in transmission of the codewords across a communication link, and the XOR codeword is configured to correct, when decoded, a second preselected number of errors in the XOR codeword (twelve in the example above) resulting during storage of the XOR codeword in a memory device or in transmission of the XOR codeword across a communication link. a XOR data value based on the XOR codeword when decoded is configured to correct a data value in a cell of the two-dimensional array having a number of errors greater than the first preselected number of errors. The decoded row and column codewords and the corrected data value in the cell of the two dimensional array comprise error free data values corresponding to the plurality of data values stored in the memory device or transmitted across a communication link. Method 1000 ends at block 1014.

In an embodiment, the disclosure includes means for mapping an address space of a buffer, wherein the buffer is configured to store a plurality of data values into a first two-dimensional array of values. For each row in the first two-dimensional array, a row parity value is calculated, wherein for each row, a plurality of data values in the row and the row parity value form a row codeword. For each column in the first two-dimensional array, a column parity value is calculated, wherein for each column, a plurality of data values in the column and the column parity value form a column codeword. The XOR of the plurality of data values is calculated. The communication system includes means for calculating a parity value based on the XOR of the plurality of data values. The XOR of the plurality of data values and the parity value based on the XOR of the plurality of data values form an XOR codeword.

In another embodiment, the disclosure includes an apparatus having means for mapping an address space of a buffer to a two-dimensional array. The apparatus also includes means for receiving a plurality of data values mapped from the buffer address space to the two-dimensional array, means for calculating a row parity value for the data values in each row of the two-dimensional array, and means for calculating a column parity value for the data values in each row of the two-dimensional array. Also included is means for calculating the XOR of the data values, means for calculating an XOR parity value based on the XOR of the data values, and means for storing each row parity value, each column parity value, and XOR parity value in the buffer.

In yet another embodiment, the disclosure includes a communication system including means for mapping an address space of the first buffer into a first two-dimensional array. The communication system also includes means for receiving a plurality of data values mapped from the first buffer address space to the first two-dimensional array, means for calculating a row parity value for the data values in each row of the first two-dimensional array, and means for calculating a column parity value for the data values in each row of the first two-dimensional array. Also included is means for calculating the XOR of the data values, means for calculating an XOR parity value based on the XOR of the data values, and means for storing each row parity value, each column parity value and XOR parity value in the buffer. The row and column parity values and corresponding row and column parity values form row and column codewords, respectively, and the XOR of the data values and the XOR parity value comprise an XOR codeword. The communication system includes means for forwarding the row, column and XOR codewords. The communications system also includes means for storing row, column and XOR codewords received over the communications link, and means for mapping an address space of the second buffer into a second two-dimensional array corresponding to the first two dimensional array. The communication system includes means for receiving a plurality of codewords mapped from the second buffer address space to the second two-dimensional array, means for decoding the row codewords and column codewords to recover the plurality of data values, and means for decoding the XOR codeword. If, based on the decoded row and column codewords, one or more errors remains in a data value, communication system includes means for correcting the one or more errors based on the decoded XOR codeword.

For the purpose of clarity, any one of the foregoing embodiments may be combined with any one or more of the other foregoing embodiments to create a new embodiment within the scope of the present disclosure.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A method comprising:
mapping an address space of a buffer configured to store a plurality of data values into a first two-dimensional array of values;
calculating, by a processor comprising an encoder, for each row in the first two-dimensional array, a row parity value, wherein for each row, a plurality of data values in the row and the row parity value form a row codeword;
calculating, by the processor comprising an encoder, for each column in the first two-dimensional array, a column parity value, wherein for each column, a plurality of data values in the column and the column parity value form a column codeword;
calculating, an exclusive-OR (XOR) of the plurality of data values; and
calculating, by the processor comprising an encoder, a parity value based on the XOR of the plurality of data values, wherein the XOR of the plurality of data values and the parity value based on the XOR of the plurality of data values form an XOR codeword, and
wherein the XOR codeword is configured to correct, when decoded, a second preselected number of errors in the XOR codeword.

2. The method of claim 1 further comprising storing the row codewords, column codewords, and XOR codeword in a flash memory device, wherein the row codewords and the column codewords are configured to correct, when decoded, a first preselected number of errors in each row and column codeword resulting during storage of the codewords in the flash memory device.

3. The method of claim 2 further comprising:
retrieving the row codewords, column codewords and XOR codeword from the flash memory device;
storing the retrieved row codewords, column codewords, and XOR codeword in a buffer;
mapping the row and column codewords to a second two-dimensional array corresponding to the first two-dimensional array; and
correcting one or more errors in the plurality of data values and parity values, by:
decoding each row and column codeword; and
correcting the errors based on the XOR codeword when one or more errors remain in a data value.

4. The method of claim 1 further comprising transmitting the row codewords, column codewords, and XOR codeword over a communication link to a receiver coupled thereto.

5. The method of claim 4 further comprising storing the received data values and parity values at a receiver buffer.

6. The method of claim 5 further comprising correcting one or more errors in the plurality of data value transmitted across the communications link, by:
mapping, by a processor comprising a buffer controller, the address space of the receiver buffer to a second two dimensional array corresponding to the first two dimensional array;
decoding, by a processor comprising a decoder, each row codeword and column codeword; and
correcting the errors based on the XOR codeword when one or more errors remain in a data value.

7. The method of claim 1, wherein calculating the row parity values and column parity values comprises calculating the row parity values and the column parity values based on a Bose-Chaudhuri-Hocquenghem (BCH) encoding.

8. The method of claim 1, wherein calculating the parity value based on the XOR of the plurality of data values comprises calculating the parity value based on a Bose-Chaudhuri-Hocquenghem (BCH) encoding.

9. The method of claim 8, wherein the XOR codeword comprises a BCH codeword having a preselected number of bits and a capability of correcting the preselected number of bits.

10. The method of claim 3 wherein an uncorrected bit error rate (UBER) is not greater than 10⁻¹⁵.

11. The method of claim 3 wherein an uncorrected bit error rate (UBER) is less than or equal to 10⁻¹⁵ at a bit error rate (BER) of less than or equal to 0.0055.

12. An apparatus comprising:
a buffer controller configured to map an address space of a buffer to a two-dimensional array;
an encoder coupled to the buffer controller configured to:
receive a plurality of data values mapped from the buffer address space to the two-dimensional array;
calculate a row parity value for the data values in each row of the two-dimensional array;
calculate a column parity value for the data values in each row of the two-dimensional array; and
exclusive-OR (XOR) logic coupled to an encoder and configured to calculate the XOR of the data values,
wherein the encoder is further configured to calculate an XOR parity value based on the XOR of the data values, and
wherein the buffer controller is further configured to store each row parity value, each column parity value, and XOR parity value in the buffer.

13. The apparatus of claim 12, wherein the row data values and column data values and corresponding row parity values and column parity values form row codewords and column codewords, respectively, and wherein the XOR of the data values and the XOR parity value comprise an XOR codeword.

14. The apparatus of claim 12 wherein, the row parity values and column parity values are based on a Bose-Chaudhuri-Hocquenghem (BCH) encoding, wherein the row codewords and the column codewords comprise a preselected number of bits, and wherein the BCH encoding is capable of correcting a preselected number of errors.

15. The apparatus of claim 12, wherein the XOR parity value is based on a Bose-Chaudhuri-Hocquenghem (BCH) encoding, wherein an XOR codeword comprises a preselected number of bits, and wherein the BCH encoding is capable of correcting a preselected number of errors.

16. The apparatus of claim 15, wherein the preselected number of bits in the XOR codeword is 255 and the preselected number of errors is twelve.

17. The apparatus of claim 13 further comprising a decoder configured to decode the row codewords, the column codewords and the XOR codeword.

18. The apparatus of claim 17, wherein, the XOR logic is further configured to correct one or more errors based on a decoded XOR codeword when, based on decoded row and column codewords, one or more errors remains in a data value.

19. The apparatus of claim 18, wherein the XOR logic is further configured to calculate the exclusive-OR of all uncorrupted data values and an XOR value from the decoded XOR codeword.

20. A communication system comprising:
a transmitter system;
a receiver system; and
a communications link between the transmitter system and the receiver system,
wherein the transmitter system comprises:
a processor comprising a first buffer controller and an encoder;
a first buffer coupled to the first buffer controller, wherein the first buffer controller is configured to map an address space of the first buffer into a first two-dimensional array;
wherein the encoder is coupled to the first buffer controller and configured to:
receive a plurality of data values mapped from the first buffer address space to the first two-dimensional array;
calculate a row parity value for the data values in each row of the first two-dimensional array;
calculate a column parity value for the data values in each row of the first two-dimensional array; and
a processor coupled to an encoder and comprising a first exclusive-OR (XOR) logic configured to calculate the XOR of the data values, wherein the encoder is further configured to calculate an XOR parity value based on the XOR of the data values, and wherein the first buffer controller is further configured to store each row parity value, each column parity value and the XOR parity value in the first buffer wherein the row and column parity values and corresponding row and column parity values form row and column codewords, respectively, and wherein the XOR of the data values and the XOR parity value comprise an XOR codeword; and
a transmitter coupled to the first buffer controller and the communications link, wherein the first buffer controller is further configured to forward the row, column and XOR codewords to the transmitter, and
wherein the receiver system comprises:
a receiver coupled to the communications link;
a second processor comprising a buffer controller coupled to the receiver, and a decoder;
a second buffer coupled to the second buffer controller, wherein the second buffer is configured to store the row codewords, the column codewords and the XOR codeword received across the communications link, and wherein the second buffer controller is configured to map an address space of the second buffer into a second two-dimensional array corresponding to the first two dimensional array;
wherein the decoder is configured to:
receive a plurality of codewords mapped from the second buffer address space to the second two-dimensional array;
decode the row codewords and column codewords to recover the plurality of data values; and
decode the XOR codeword; and
a second XOR logic coupled to the decoder wherein, the second XOR logic is configured to correct the one or more errors based on the decoded XOR codeword when based on the decoded row and column codewords, one or more errors remains in a data value.

21. The communication system of claim 20, wherein the second XOR logic is configured to correct the one or more errors by calculating the exclusive-OR of all uncorrupted data values and an XOR value from the decoded XOR codeword.

22. The communication system of claim 21, wherein the XOR codeword is based on a Bose-Chaudhuri-Hocquenghem (BCH) encoding having a preselected number of bits in the XOR codeword and a capability of correcting a preselected number of errors.
